(19) United States
(12) Patent Application Publication
(10) Pub. No.: US 2024/0145600 A1
(43) Pub. Date: May 2, 2024

(54) SEMICONDUCTOR DEVICE, METHOD OF MANUFACTURING OXIDE FILM AND METHOD FOR SUPPRESSING GENERATION OF LEAKAGE CURRENT

(71) Applicant: Taiwan Semiconductor Manufacturing Company, Ltd., Hsinchu (TW)

(72) Inventors: Wei-Chih WEN, Hsinchu (TW); Yi-Lin YANG, Hsinchu (TW); Hai-Ching CHEN, Hsinchu (TW)

(73) Assignee: Taiwan Semiconductor Manufacturing Company, Ltd., Hsinchu (TW)

(21) Appl. No.: 18/099,482

(22) Filed: Jan. 20, 2023

Related U.S. Application Data
(60) Provisional application No. 63/421,702, filed on Nov. 2, 2022.

(51) Int. Cl. H01L 29/786; H01L 29/417; H01L 29/66

(52) U.S. Cl. CPC H01L 29/78693; H01L 29/41733; H01L 29/6675; H01L 29/78609

(57) ABSTRACT

A semiconductor device includes a gate electrode, a gate insulating layer, an active layer, a source electrode and a drain electrode. The gate insulating layer is disposed between the gate electrode and the active layer, the source electrode and the drain electrode are arranged on one side of the gate insulating layer, wherein the gate insulating layer includes multilayer oxide films stacked on each other and at least one interface layer between the multilayer oxide films, and the material of the at least one interface layer is different from the material of the oxide films.

### PRIORITY CLAIM AND CROSS-REFERENCE

This application claims the benefit of U.S. provisional application Ser. No. 63/421,702, filed Nov. 2, 2022, the subject matter of which is incorporated herein by reference.

### BACKGROUND

In the back-end of line of semiconductor manufacturing process related to transistors, the oxide film of high dielectric constant will be crystallized due to high temperature annealing, and there will be more and more oxygen vacancies among the grain-boundaries of the oxide film, which will cause serious leakage current and easy to induce the joule heating effect at high bias voltage, and the time-dependent dielectric breakdown (TDDB) performance will deteriorate accordingly. For the above reasons, it is needed to be further improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of a semiconductor device according to an embodiment of the present disclosure.

FIGS. 2A and 2B are schematic diagrams illustrating a method for manufacturing an oxide film according to a conventional comparative example.

FIGS. 3A to 3C are schematic diagrams illustrating a method for manufacturing an oxide film according to an embodiment of the present disclosure.

FIG. 4A is a schematic diagram illustrating the generation of leakage current caused by vacancies between grain-boundaries according to a conventional comparative example.

FIG. 4B is a schematic diagram illustrating the use of an amorphous oxide interface layer to suppress the generation of leakage current according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

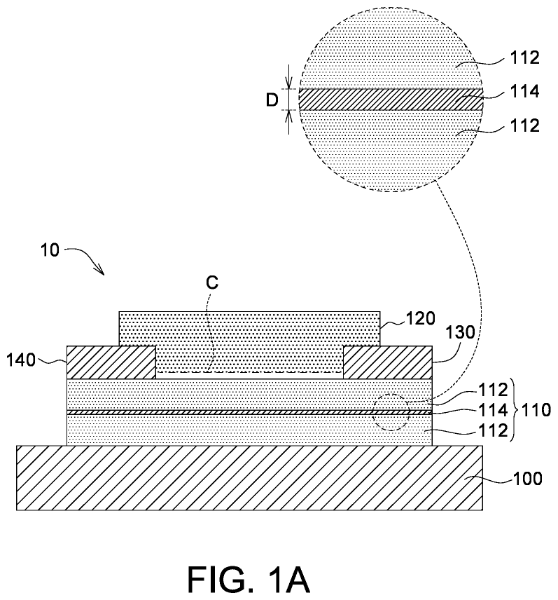

Please refer to FIGS. 1A and 1B. FIGS. 1A and 1B are schematic diagrams of a semiconductor device 10, 11 according to an embodiment of the present disclosure, respectively. Although these embodiments take the thin film transistor having the bottom gate electrode 100 as an example, the present disclosure is not limited thereto, and can also be implemented by other embodiments. The difference between the semiconductor device 10 in FIG. 1A and the semiconductor device 11 in FIG. 1B is that the gate insulating layer 110 in FIG. 1A includes two layers of oxide films 112 and an interface layer 114, while the gate insulating layer 110 in FIG. 1B includes more than two layers of oxide films 112 (for example, four layers) and two or more interface layers 114 (for example, three layers).

The semiconductor devices 10, 11 include a gate electrode 100, a gate insulating layer 110, an active layer 120, a source electrode 130 and a drain electrode 140. The gate insulating layer 110 is disposed between the gate electrode 100 and the active layer 120, the source electrode 130 and the drain electrode 140 are disposed on one side of the gate insulating layer 110, wherein the gate insulating layer 110 includes multilayer oxide films 112 and at least one interface layer 114, the at least one interface layer 114 is formed between the oxide films 112, and the material of the at least one interface layer 114 is different from the material of the oxide films 112. For example, the dielectric constant of the at least one interface layer 114 is lower than the dielectric constant of the oxide films 112.

The material of the gate electrode 100 includes chromium (Cr), molybdenum (Mo), copper (Cu), aluminum (Al), tungsten (tungsten), titanium (titanium) or combinations thereof, but the disclosure is not limited thereto. The gate insulating layer 110 is formed on the gate electrode 100. The gate insulating layer 110 may be a dielectric material including silicon oxide (SiOx), aluminum oxide (AlOx), hafnium oxide: zirconium oxide (HfOx: ZrOx), hafnium oxide: aluminum oxide (HfOx: AlOx), hafnium oxide: oxide Lanthanum (HfOx: LaOx), Hafnium Oxide: Silicon Oxide (HfOx: SiOx), Hafnium Oxide: Strontium Oxide (HfOx: SrO), Hafnium Zirconium Oxide (HZO) doped with cerium oxide (CeOx), etc. The active layer 120 is formed on the gate insulating layer 110, and the material of the active layer 120 includes monocrystalline silicon (a-Si), polycrystalline silicon (poly-Si) or metal oxide semiconductor, such as indium zinc oxide (IZO), indium gallium oxide (IGO), indium gallium zinc oxide (IGZO), tungsten oxide (IWO), tungsten zinc oxide (IWZO), etc.

The active layer 120 is, for example, an oxide semiconductor layer, which can be formed by, for example, direct current (DC) sputtering or radio frequency (RF) sputtering, DC sputtering or RF sputtering. A sputtering target having the same composition as the oxide semiconductor layer of the active layer 120. Alternatively, the active layer 120 may be formed by a co-sputtering method using a plurality of sputtering targets.

The active layer 120 is disposed between the source electrode 130 and the drain electrode 140, and a channel region C is formed between the source electrode 130 and the drain electrode 140, and the gate electrode 100 is disposed under the channel region C for applying a gate voltage to control the current flowing through the channel region C. The types of the source electrode 130 and the drain electrode 140 are not particularly limited, and common electrode materials can be used. For example, the source electrode 130 and the drain electrode 140 may be made of Molybdenum (Mo), Chromium (Cr), Titanium (Ti) and the like or alloys. Among these materials, Cu or Cu alloy is preferably used in view of low resistivity.

The formation method of the source electrode 130 and the drain electrode 140 is not limited, for example, a metal film is formed by a magnetron sputtering method or a radio frequency (RF) sputtering method, and then a wet etching is performed with an etchant of hydrogen peroxide, phosphoric acid, nitric acid or acetic acid to remove a portion of the metal film to form a patterned metal thin film.

The method for forming the gate electrode 100 and the gate insulating layer 110 is not particularly limited, and the type of metal for forming the gate electrode 100 is also not particularly limited. For example, in the formation process of the gate electrode 100, metals such as aluminum (Al) and copper (Cu) with low resistivity, or molybdenum (Mo), chromium (Cr), titanium (Ti) with high heat resistance or one of the alloys of these metals are preferably selected.

In addition, in the formation of the gate insulating layer 110, oxides such as SiOx, SiNx, AlOx, or HfOx can be selectively used. In addition, as the gate insulating layer 110, for example, multiple oxide layers of high dielectric constant can be continuously formed. The built-up oxide films 112 can increases the dielectric constant. Therefore, the thickness of the built-up gate insulating layer 110 is thicker than that of the conventional gate insulating layer using SiO₂. In FIG. 1A, the gate insulating layer 110 has, for example, two-layer oxide films 112, and in FIG. 1B, the gate insulating layer 110 has, for example, four-layer oxide films 112, and the number of layers of oxide films 112 can be 2 to 10, the total height of the oxide films 112 is, for example, 30 to 200 angstroms, but the present disclosure is not limited thereto.

In addition, the semiconductor device 10 has higher requirements for the carrier mobility of thin film transistors and the dielectric breakdown performance caused by leakage current. At the same time, in order to reduce power consumption, reduce the operating voltage of thin film transistors is also an important issue. In this embodiment, an interface layer 114 is added to two adjacent oxide films 112 to improve the defect content of the oxide films 112 and improve the electrical stability of the transistor.

In some embodiments, the oxide film 112 with high dielectric constant is, for example, hafnium oxide (HfO), zirconium oxide (ZrO), titanium oxide (TiO2), hafnium zirconium oxide (HZO), or a combination thereof. The dielectric constant of hafnium oxide (HfO) and zirconium oxide (ZrO) is about 25, which is greater than the dielectric constant (about 3.9) of silicon dioxide (SiO₂), which is conventionally used as the gate insulating layer. Since the dielectric constant of silicon dioxide (SiO₂), conventionally used as the gate insulating layer, is too low to overcome the influence of the tunneling effect, the oxide film 112 with high dielectric constant has gradually replaced the silicon oxide (SiO₂) to become the mainstream gate insulating layer.

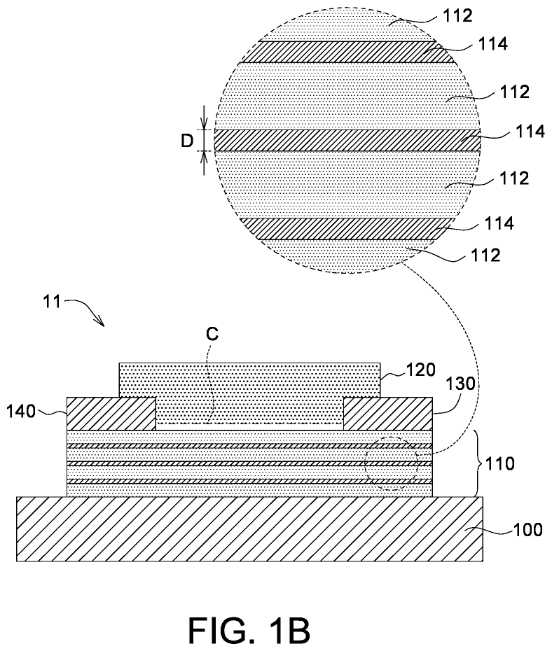

FIGS. 2A to 2B are schematic diagrams illustrating a method of manufacturing an oxide film 120′ according to a conventional comparative example. Taking hafnium oxide (HfO) as an example, hafnium oxide (HfO) can be grown directly on silicon substrate and has the advantages of better thermal stability, higher dielectric constant, and relatively large energy vacancies width, but it still have to solve problems such as the decrease of electron mobility and the instability of threshold voltage. In addition, the oxide film 112′ with high dielectric constant can achieve the same equivalent oxide thickness (EOT) at a thicker physical thickness, which is expected to reduce the tunneling current of its gate insulating layer. However, as shown in FIGS. 2A and 2B, when the thickness D1 of the conventional oxide film 112′ is larger than a thickness to be crystallized Dc (e.g., 15-30 angstroms), the oxide film 112′ may undergo a crystal phase change due to high temperature treatment, so that the oxide film 112′ may changes from the amorphous phase (phase 1) to the polycrystalline phase (phase 2), and the vacancies V between the grain-boundaries will cause serious leakage current, and it is easy to induce the current thermal effect (or Joule heating) to make the time-dependent dielectric breakdown (TDDB) performance deteriorate, so that the oxide film 112′ in the conventional method has a problem of poor reliability.

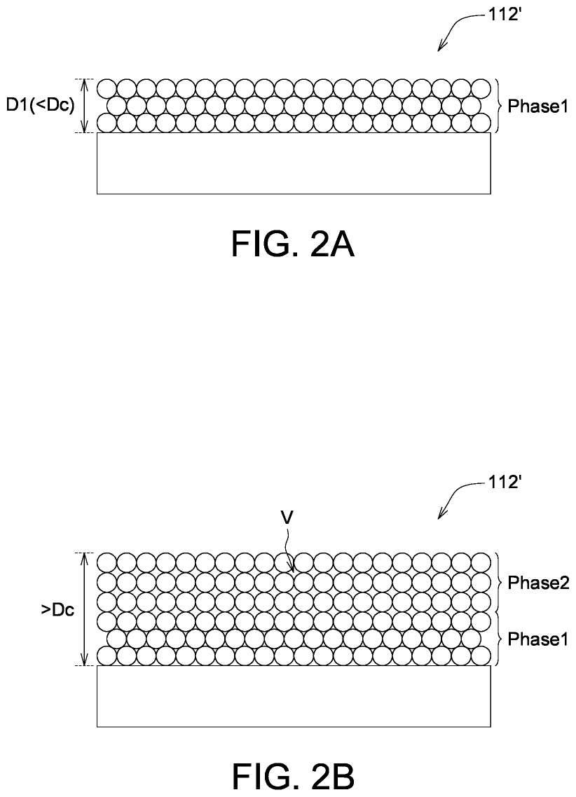

Please refer to FIGS. 3A to 3C, which are schematic diagrams illustrating a method for manufacturing the oxide films 112 according to an embodiment of the present disclosure. In order to improve the reliability of the oxide films 112, in this embodiment, the crystal phase reaction of each oxide film 112 is controlled to avoid crystallization of the oxide films 112, and the interface layer 114 between two adjacent oxide films 112. the interface layer 114 can block between the grain boundaries of the oxide films 112, so as to prevent the generation of leakage current paths. In addition, the interface layer 114 is, for example, an oxide with a low dielectric constant such as silicon oxide (SiOx), aluminum oxide (AlOx), titanium oxide (TiOx) or Tantalum oxide (TaOx) or other metal-oxides etc., which has a Gibbs free energy (GFE) higher than the oxide film 112 with a high dielectric constant, such that less oxygen vacancies and less current conduction paths are generated to prevent too many current conduction paths connected in the grain boundaries and passing through the gate insulating layer 110.

Please refer to FIGS. 3A to 3C, the manufacturing method of the oxide film 112 includes the following steps. First, in FIG. 3A, a first oxide film 112a with high dielectric constant is formed on a substrate 111, the first oxide film 112a is in an amorphous state, and the thickness D1 of the first oxide film 112a is less than a thickness to be crystallized Dc, for example, less than 15 or less than 30 angstroms. The method for forming the first oxide film 112a is, for example, physical vapor deposition (PVD), chemical vapor deposition (CVD) or atomic layer deposition (ALD), PVD deposition usually includes sputtering deposition, cathode arc deposition, electron beam deposition, etc.

Next, in FIG. 3B, an interface layer 114 is formed on the first oxide film 112a. The interface layer 114 is formed by, for example, atomic layer deposition. The thickness of the interface layer 114 is, for example, less than or equal to 2 angstroms. The interface layer 114 is, for example, an amorphous oxide, and the dielectric constant of the interface layer 114 is, for example, lower than that of the first oxide film 112.

In FIG. 3C, a second oxide film 112b with high dielectric constant is formed on the interface layer 114, so that the first and second oxide films 112a, 112b are stacked on each other and the interface layer 114 is disposed between the first and second oxide films 112a, 112b. The thickness D2 of the second oxide film 112b is less than a thickness to be crystallized Dc, for example, less than 15 or less than 30 angstroms. The interface layer 114 can make the upper second oxide film 112b re-grow a new amorphous oxide, and the amorphous interface layer 114 can disturb the lower first oxide film 112a to continue to grow a crystallized oxide, so that the first and second oxide thin films 112a and 112b can be suppressed from being transformed from an amorphous phase to a polycrystalline phase.

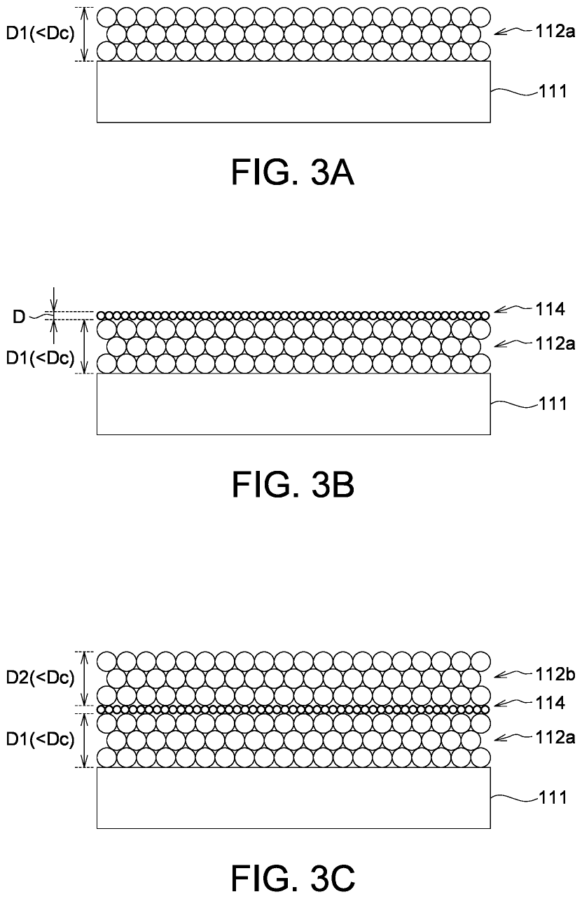

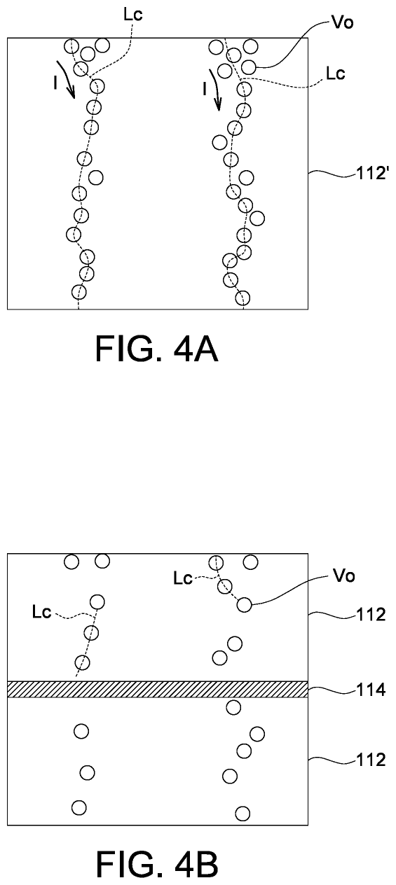

Please refer to FIGS. 4A and 4B. FIG. 4A shows a schematic diagram of the generation of leakage current I caused by the vacancies between the grain-boundaries according to a conventional comparative example, and FIG. 4B shows the use of the amorphous oxide interface layer 114 to suppress the generation of leakage current according to an embodiment of the present disclosure. In FIG. 4A, the conventional oxide film 112′ with high dielectric constant is crystallized due to high temperature annealing, the oxygen vacancies Vo between the grain-boundaries will become more and more, and charged oxygen vacancies Vo can also line up during field stress to form another kind of leakage path, which will cause serious leakage current I and easy to induce the joule heating effect at high bias voltage, and the time-dependent dielectric breakdown (TDDB) performance will deteriorate accordingly. For example, in the HfO oxide film 112′, oxygen vacancies capture electrons to form negatively charged oxygen vacancies (Vo²⁻), while the oxygen vacancy energy on other main bonds (Back-Bond) will be reduced due to the Coulomb force, resulting in other oxygen vacancies Vo being formed, and after the chain effect of oxygen vacancies Vo is generated, electrons are injected into the HfO oxide film 112′ through the gate electrode, resulting in the generation of the leakage current path Lc, so that the HfO oxide film 112′ can easily occur hard breakdown due to defect accumulation. In FIG. 4B, an amorphous oxide interface layer 114 is formed between two adjacent oxide films 112 with high dielectric constant, and the amorphous oxide interface layer 114 can make oxide grow on it back to nucleation stage and suppress crystallization phenomenon in the oxide films 112, and make oxide films 112 hard to form oxygen vacancies Vo and the oxygen vacancies Vo line-up will be ended up, so that the oxide films 112 with high dielectric constant have less oxygen vacancies to form less current conduction paths. If more amorphous oxide interface layers 114 are formed (as shown in FIG. 1B) between two adjacent layers of the oxide films 112 with high dielectric constant, the effect of suppressing the generation of the leakage current path Lc will be better, and the time-dependent dielectric breakdown (TDDB) performance and the reliability of the gate insulating layer 110 are improved accordingly.

In these embodiments, since the defect of oxygen vacancies is improved, depending on the current-voltage (I-V) characteristic diagram, the gate insulating layer 110 of the semiconductor device 10 has a lower leakage current and a higher breakdown voltage, thereby improving the reliability of the semiconductor device 10.

The disclosure is directed to a semiconductor device, a method for manufacturing an oxide thin film and a method for suppressing the generation of leakage current to improve the reliability of the semiconductor device. Based on the present disclosure, the problems of the oxide film of high dielectric constant crystallized due to high temperature annealing and more and more oxygen vacancies among the grain-boundaries, and oxygen vacancies line-up during field stress causing serious leakage current will be improved by an amorphous oxide interface layer formed between two adjacent oxide films with high dielectric constant, and the amorphous oxide interface layer can suppress the initial stage of micro-crystallization phenomenon in the oxide films, so that the oxide films with high dielectric constant have less oxygen vacancies to form less current conduction paths, and the time-dependent dielectric breakdown (TDDB) performance and the reliability of the gate insulating layer are improved accordingly.

In some embodiments of the present disclosure, a semiconductor device is provided, which includes a gate electrode, a gate insulating layer, an active layer, a source electrode, and a drain electrode. The gate insulating layer is disposed between the gate electrode and the active layer, the source electrode and the drain electrode are arranged on one side of the gate insulating layer, wherein the gate insulating layer comprises multilayer oxide films stacked on each other and at least one interface layer formed between the oxide films, and the material of the at least one interface layer is different from the material of the oxide films.

In some embodiments of the present disclosure, a method of manufacturing an oxide film is provided, which includes the following steps. A first oxide film with high dielectric constant is formed on a substrate, and the thickness of the first oxide film is smaller than a thickness to be crystallized. An interface layer is formed on the first oxide film. A second oxide film with high dielectric constant is formed on the interface layer, the thickness of the second oxide film is less than a thickness to be crystallized, wherein the first and second oxide films are stacked on each other and the interface layer is disposed between the first and second oxide films.

In some embodiments of the present disclosure, a method for suppressing the generation of leakage current using an amorphous oxide interface layer is provided for a gate insulating layer, and the gate insulating layer includes multilayer oxide films stacked on each other. The method for suppressing the generation of leakage current includes forming at least one amorphous oxide interface layer between two adjacent layers of the multilayer oxide films.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a gate electrode;
a gate insulating layer;
an active layer, wherein the gate insulating layer is disposed between the gate electrode and the active layer;
a source electrode; and
a drain electrode, wherein the source electrode and the drain electrode are disposed on a side of the gate insulating layer, the gate insulating layer comprises multilayer oxide films stacked on each other and at least one interface layer formed between the multilayer oxide films, a material of the at least one interface layer is different from a material of the multilayer oxide films.

2. The semiconductor device according to claim 1, wherein the at least one interface layer is an amorphous oxide.

3. The semiconductor device according to claim 1, wherein a thickness of the at least one interface layer is less than or equal to 2 angstroms.

4. The semiconductor device according to claim 1, wherein the multilayer oxide films comprise a material selected from hafnium oxide (HfO), zirconium oxide (ZrO), hafnium zirconium oxide (HZO), or a combination thereof.

5. The semiconductor device according to claim 1, wherein a dielectric constant of the at least one interface layer is lower than a dielectric constant of the multilayer oxide films.

6. The semiconductor device according to claim 1, wherein a number of layers of the oxide films is 2 to 10.

7. The semiconductor device according to claim 1, wherein the multilayer oxide films have a total height of 30 to 200 angstroms.

8. A method of manufacturing an oxide film, comprising:
forming a first oxide film with high dielectric constant on a substrate, a thickness of the first oxide film is less than a thickness to be crystallized;
forming an interface layer on the first oxide film; and
forming a second oxide film with high dielectric constant on the interface layer, a thickness of the second oxide film is smaller than the thickness to be crystallized;
wherein the first and second oxide films are stacked on each other, and the interface layer is disposed between the first and second oxide films.

9. The manufacturing method according to claim 8, wherein the interface layer is an amorphous oxide.

10. The manufacturing method according to claim 8, wherein a thickness of the interface layer is less than or equal to 2 angstroms.

11. The manufacturing method according to claim 8, wherein a material of the first and second oxide films comprises hafnium oxide (HfO), zirconium oxide (ZrO), hafnium zirconium oxide (HZO) or a combination thereof.

12. The manufacturing method according to claim 8, wherein a dielectric constant of the interface layer is lower than a dielectric constant of the first and second oxide films.

13. The manufacturing method according to claim 8, wherein the thickness to be crystallized is between 15-30 angstroms.

14. A method for suppressing a generation of leakage current for a gate insulating layer, the gate insulating layer comprising multilayer oxide films stacked on each other, the method for suppressing the generation of leakage current comprising forming at least one amorphous oxide interface layer between two adjacent layers of the multilayer oxide films.

15. The method according to claim 14, wherein a material of the interface layer comprises silicon oxide (SiOx), aluminum oxide (AlOx), titanium oxide (TiOx), Tantalum oxide (TaOx) or metal-oxides with Gibbs free energy (GFE) higher than the oxide film.

16. The method according to claim 14, wherein a thickness of the interface layer is less than or equal to 2 angstroms.

17. The method according to claim 14, wherein a material of the multilayer oxide films comprise hafnium oxide (HfO), zirconium oxide (ZrO), hafnium zirconium oxide (HZO), or a combination thereof.

18. The method according to claim 14, wherein a dielectric constant of the interface layer is lower than a dielectric constant of the multilayer oxide films.

19. The method according to claim 14, wherein a number of layers of the oxide films is 2 to 10.

20. The method according to claim 14, wherein the multilayer oxide films have a total height of 30 to 200 angstroms.
